(19) United States
(12) Patent Application Publication
(10) Pub. No.: US 2011/0062554 A1
(43) Pub. Date: Mar. 17, 2011

(54) HIGH VOLTAGE FLOATING WELL IN A SILICON DIE

(76) Inventors: Michael R. Hsing, Saratoga, CA (US); James C. Moyer, San Jose, CA (US)

(21) Appl. No.: 12/562,083

(22) Filed: Sep. 17, 2009

(51) Int. Cl. H01L 27/06

(52) U.S. Cl. 257/536; 257/E27.013

(57) ABSTRACT

In one embodiment, a graded n-doped region surrounding a well, and a spiral resistor connected to the well and to a p-doped region surrounding the graded n-doped region.

### FIELD

The present invention relates to semiconductor electronics.

### BACKGROUND

Many DC-to-DC power converters may be conceptualized by the circuit illustrated in FIG. 1, where electrical power from a source having a supply voltage V_{IN} is provided to load 102 such that the load voltage is regulated to some voltage less than V_{IN}. A feedback path is provided from node 103 to controller 104, where controller 104 controls the duty cycle of high-side switch 106 and low-side switch 108 to regulate the load voltage. A second-order low pass filter comprising inductor 110 and capacitor 112 couples load 102 to switch point 114 so as to smooth output ripples. In practice, switches 106 and 108 are power MOSFETs (Metal-Oxide-Semiconductor-Field-Effect-Transistor), where each power MOSFET is realized by a large number of individual MOSFETs connected in parallel. The operating principles for the circuit of FIG. 1 are well known to those skilled in the art of power converters, and need not be repeated here.

For some consumer applications, the supply voltage V_{IN} may peak to several hundred volts, in which case the voltage drop across switch 106 or 108 may also peak to several hundred volts. Accordingly, for such applications, switches 106 and 108 should be designed to operate under such high voltage drops.

In practice, most or all of the circuit components in an embodiment, except for inductor 110, capacitor 112, load 102, and perhaps some discrete resistors and capacitors, are integrated on a single silicon die. Some circuit components within controller 104 may be connected to the supply voltage V_{IN}. However, various circuit components within controller 104 may in practice be designed to operate over voltage drops not to exceed on the order of ten volts. For example, a circuit block within controller 104 may be connected to a high voltage pin, yet the circuit block may be designed for voltage drops not to exceed on the order of ten volts. Accordingly, it is desirable to electrically isolate such circuits from high voltage drops to avoid device breakdown.

### BRIEF DESCRIPTION OF THE DRAWINGS

FIG. 1 illustrates a prior art DC-to-DC power converter.

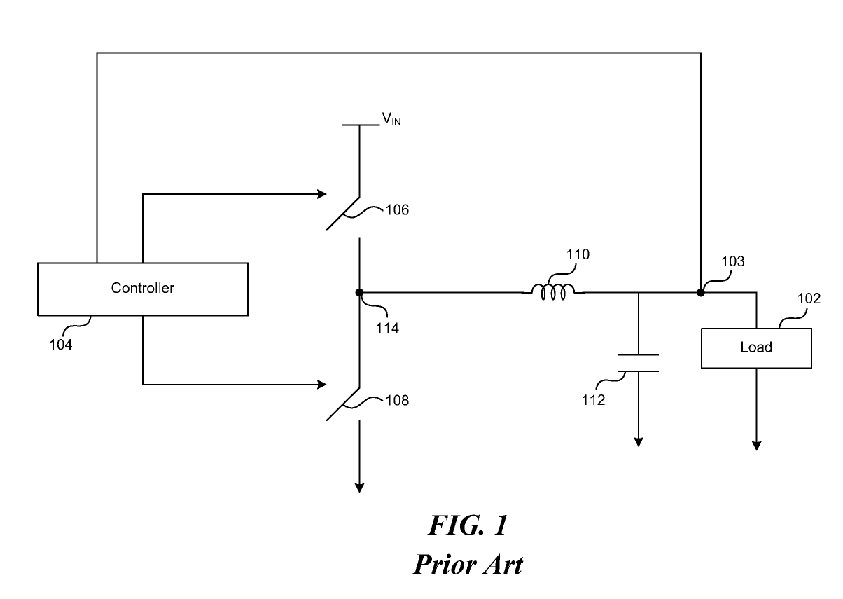

FIG. 2 illustrates a cross-sectional plan view of an embodiment.

FIG. 3 illustrates a top plan view of an embodiment.

### DESCRIPTION OF EMBODIMENTS

In the description that follows, the scope of the term “some embodiments” is not to be so limited as to mean more than one embodiment, but rather, the scope may include one embodiment, more than one embodiment, or perhaps all embodiments.

Although embodiments find application to DC-to-DC power converters, embodiments are not limited to such applications. In this Description of Embodiments, the region of the silicon die that is electrically isolated from high voltage drops may be termed a floating well.

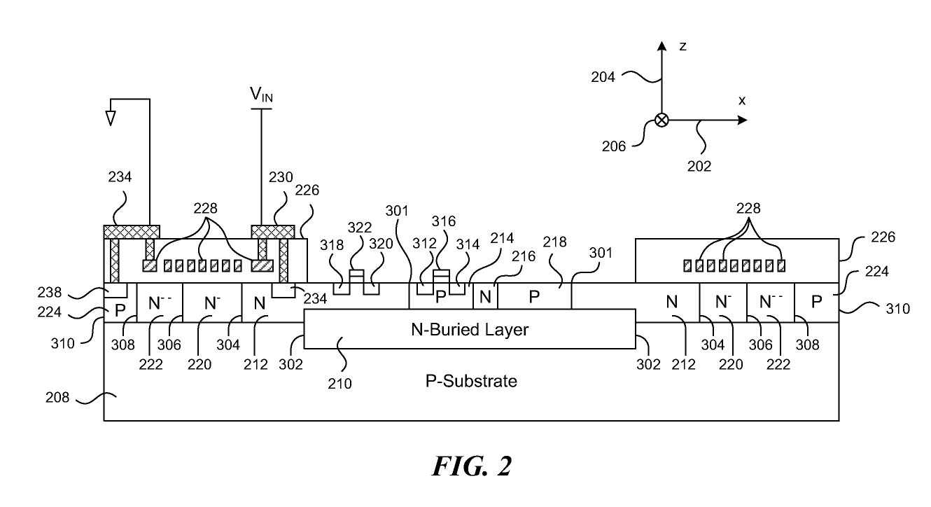

FIG. 2 illustrates a cross-sectional plan view of a portion of a silicon die according to an embodiment. For ease of illustration, FIG. 2 is not drawn to scale, and various doped regions are idealized as rectangles. For reference, shown in FIG. 2 is a coordinate system with x-axis 202 and z-axis 204 lying in the plane of illustration, with y-axis 206 pointing into the plane of the illustration. With the coordinate system as shown, the cross-sectional view illustrated in FIG. 2 is taken as a slice of an embodiment, with the slice perpendicular to y-axis 206.

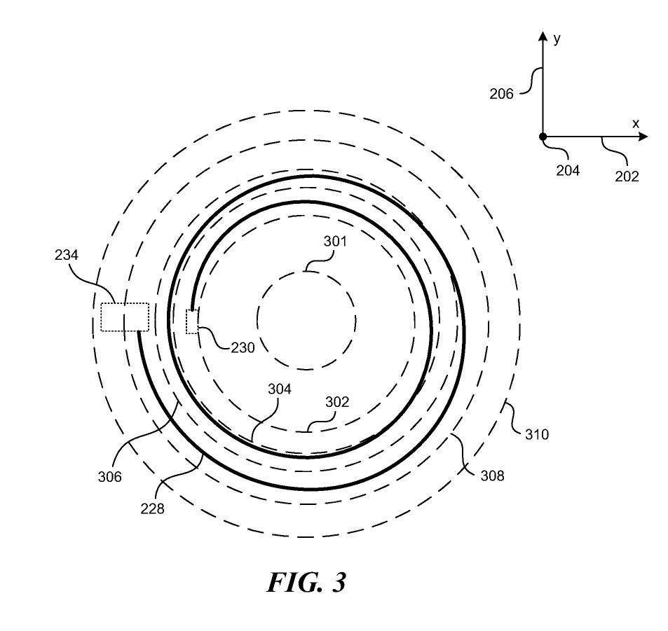

FIG. 3 illustrates a cross-sectional plan view of a portion of the silicon die according to an embodiment, but with a different view than that of FIG. 2. To provide relative orientations of the embodiment of FIG. 2 and the embodiment of FIG. 3, the coordinate system in FIG. 2 is also shown in FIG. 3, making clear that the cross-sectional view illustrated in FIG. 3 is a slice of an embodiment, with the slice taken perpendicular to z-axis 204. For ease of illustration, FIG. 3 is not drawn to scale.

Referring to FIG. 2, formed in p-doped substrate 208 is n-doped buried layer 210. Adjacent to n-doped buried layer 210 are several regions of the silicon die, where for simplicity only three such regions are illustrated in FIG. 2, and are labeled 212, 214, 216, and 218. Regions 212 and 216 are n-doped regions, and regions 214 and 218 are p-doped regions. Other embodiments may have more or less such regions adjacent to n-doped buried layer 210, but the outermost region adjacent to n-doped buried layer 210 is n-doped.

Region 212 in FIG. 2 appears noncontiguous only because of the way the slice is taken to provide the view of the illustration, but for the embodiments of FIGS. 2 and 3, region 212 is contiguous and surrounds n-doped buried layer 210. This is made clear by the view illustrated in FIG. 3, where dashed circle 302 in FIG. 3 corresponds to outer edge 302 of n-doped buried layer 210 in FIG. 2, and dashed circles 304 and 306 in FIG. 3 correspond, respectively, to junctions 304 and 306 in FIG. 2, where junction 304 is the junction between n-doped regions 212 and 220, and junction 306 is the junction between n-doped regions 220 and 222.

Region 212 lies between dashed circles 301 and 304 in FIG. 3, and is shown as an annulus. However, in practice n-doped region 212 may not be exactly circular in shape, and for some embodiments, n-doped region 212 may take on other geometric shapes, or it may be irregular.

In FIG. 2, labels 214 and 218 may refer to the same region. That is, p-doped regions 214 and 218 may be slices of the same annulus. However, different numeric labels are used because these numeric labels may represent noncontiguous regions.

Adjacent to n-doped region 212 is n-doped region 220 surrounding n-doped region 212, represented by the annulus between dashed circles 304 and 306 in FIG. 3. N-doped region 220 is doped less than n-doped region 212, as indicated by the symbol N⁻ in FIG. 2. Adjacent to n-doped region 220 is n-doped region 222 surrounding n-doped region 220, represented by the annulus between dashed circles 306 and 308 in FIG. 3. N-doped region 222 is doped less than n-doped region 220, as indicated by the symbol N⁻⁻ in FIG. 2. Adjacent to n-doped region 222 is p-doped region 224, represented by the annulus between dashed circles 308 and 310 in FIG. 3. P-doped region 224 may be part of p-substrate 208, but for ease of discussion is labeled as a distinct region. Regions 220, 222, and 224 may not be exactly circular in shape, and for some embodiments, may take on other geometric shapes, or they may be irregular.

n-doped buried layer 210 is represented by the region inside dashed circle 302 in FIG. 3. For the embodiment of FIG. 3, n-doped buried layer 210 is illustrated as having a disk shape, but other embodiments may utilize different shapes for region 210. For ease of illustration, regions 214, 216, and 218 (214 and 218 may label the same region, as discussed previously) are not shown in FIG. 3.

Referring to FIG. 2, label 226 denotes a dielectric layer, such as for example SiO₂. For ease of illustration, FIG. 2 shows that the dielectric layer on some or all of regions 212, 214, 216, and 218 above n-doped buried layer 210 has been removed, but in practice a dielectric layer may be deposited over these regions.

Formed in oxide layer 226 is spiral resistor 228. Spiral resistor 228 may also be referred to as a spiral field plate. In FIG. 2, the cross-sectional view of spiral resistor 228 is indicated by hatched rectangles. Solid spiral line 228 in FIG. 3 represents spiral resistor 228, however, a simplification is made because the number of turns of spiral resistor 228 as shown in FIG. 3 is less than the number of turns represented in FIG. 2. Also, for simplicity all turns in FIG. 3 are shown equal in thickness (in the x-y plane), whereas this is not so for FIG. 2. Furthermore, for clarity of illustration, the scale of the various regions in FIG. 3 does not match that of FIG. 2. The slice in FIG. 3 is taken along spiral resistor 228 in the x-y plane, hence other structures in FIG. 3 are shown dashed because they are present below or above (along the z-axis dimension) the slice.

The inner ring of spiral resistor 228 is electrically connected to n-doped region 212. For example, in embodiments represented by the illustrations in FIGS. 2 and 3, the inner ring of spiral resistor 228 is connected to n-doped region 212 by way of highly doped n-region 234, and by a set of vias and an interconnect, collectively labeled by the numeral 230, and shown cross-hatched in the illustration of FIG. 2 and as a dashed rectangle in FIG. 3. Region 234 is a highly doped n-region to provide a good electrical contact between spiral resistor 228 and region 212, so that highly doped n-region 234 and set of vias and interconnect 230 serve as an ohmic contact.

The outer ring of spiral resistor 228 is electrically connected to p-doped region 224. For example, in embodiments represented by the illustrations in FIGS. 2 and 3, the outer ring of spiral resistor 228 is connected to p-doped region 224 by way of highly doped p-region 238, and by a set of vias and an interconnect, collectively labeled by the numeral 234, and shown cross-hatched in the illustration of FIG. 2 and as a dashed rectangle in FIG. 3. Region 238 is a highly doped p-region to provide a good electrical contact between spiral resistor 228 and region 224, so that highly doped p-region 238 and set of vias and interconnect 234 serve as an ohmic contact.

Spiral resistor 228 may not be exactly a spiral, and for some embodiments spiral resistor 228 may not have a spiral shape. For some embodiments, spiral resistor 228 may meander from above region 212 to above region 222. Some embodiments may have spiral resistor 228 comprising straight sections, so as to enclose a region somewhat rectangular in nature, but with curved corners. Accordingly, in general, the descriptive term “spiral resistor” is not meant to imply that the resistor coupling outer p-doped region 224 to n-doped region 212 is necessarily spiral in shape.

For some embodiments, spiral resistor 228 may comprise polysilicon. Well known design techniques may be used so that spiral resistor 228 has some desired resistance. For example, for some embodiments the sheet resistance of the polysilicon used for spiral resistor 228 may be from 1KΩ/square to 5KΩ/square, and a typical resistance for spiral resistor 228 may be in the neighborhood of 60MΩ. For some embodiments, the typical radii of curvature for the bends in spiral resistor 228 may be in the neighborhood of 100 μm to 200 μm. These numerical values are given merely to provide examples. Other embodiments may have numerical values not represented by these numerical ranges or values.

Regions 212, 220, and 222 provide a graded doping profile. For simplicity, only three such graduations or steps in doping are shown, but other embodiments may have a different number of such graduations or steps in doping level. As an example of doping levels, region 212 may have a doping level in the range of 10¹⁵ cm⁻³ to 10¹⁶ cm⁻³, where the doping profile is such that region 220 is doped at 1/10 the level of region 212, and region 222 is doped at 1/10 the level of region 220. These numerical values are given merely to provide examples. Other embodiments may have numerical values not represented by these numerical ranges or values.

In practice, during operation of the circuit fabricated in the silicon die, the interconnect represented by label 230 may be at a first voltage potential, and the interconnect represented by label 234 may be at a second voltage potential different from the first voltage potential. As a result, in operation the voltage potential of region 212 and n-doped buried layer 210 may be at the first voltage potential, and p-doped region 224 may be at the second voltage potential. The difference in these voltage potentials may be relatively high, for example several hundred volts, as may be the case for consumer power converters. As a particular example, in FIG. 2 the metal interconnect represented by label 230 is shown to be at the supply voltage V_{IN}, and the metal interconnect represented by label 234 is shown to be at ground potential.

The voltage potential difference discussed above appears across spiral resistor 228, but if the resistance of spiral resistor 228 is sufficiently high, the resulting current may be set to a relatively low value to reduce wasted power and heat. Spiral resistor 228 sets the voltage potential at the surface of regions 212, 220, and 222, so as to mitigate high electric fields that may cause breakdown. The graded doping profile provided by regions 212, 220, and 222 profiles the depletion region between p-substrate 208 and n-doped regions 212, 220, 222 so that the depletion region has less depth towards p-doped region 224, thereby mitigating punch-through. Accordingly, spiral resistor 228 and the grading of the n-doping in the lateral dimension (x-y plane) help to electrically isolate regions 212, 214, 216, and 218, and n-doped buried layer 210, from parts of the silicon die that are physically placed outside of p-doped region 224. This is important for devices integrated in regions 212, 214, 216, and 218 that may be at or near the high voltage V_{IN}, but where the voltage drops across such devices may be only on the order of ten volts.

The floating well may be considered to include the doped silicon inside circular junction 304, including n-doped buried layer 210. In general, the floating well (e.g., regions 210, 212, 214, 216, and 218) may float from a relatively high voltage, such as for example +700V above ground (or the p-substrate) to a much lower positive voltage, ground voltage, or a forward biased diode voltage drop below ground. Devices and circuits within such a floating well may operate at a high voltage with respect to ground, but at a low to medium voltage with respect to the floating well.

The particular value of the substrate voltage in a packaged integrated circuit depends upon the application, so for some applications the floating well may be held at 0V and the p-doped substrate voltage may move from 0V to −700V, for example. This may be done throughout the operating voltage range, for example, the floating well may be at −350V and the p-doped substrate at −350V, and so forth. For some embodiments, the volume resistivity of p-doped substrate 208 may be in the neighborhood of 80 ohm-cm, or greater, so that a breakdown voltage of about 700V may be obtained between n-doped buried layer 210 and p-doped substrate 208, whereas spiral resistor 228 and graded regions 212, 220, and 222 provide for a high breakdown voltage in the lateral dimension (x-y plane).

All devices within the floating well may be electrically isolated from the substrate, up to some breakdown voltage. P-well regions within the floating well, for example regions 214 and 218, may be electrically isolated from each other by the n-well regions within the floating well. For example, depending upon the device layout and the process technology used, devices within each p-well region may have an operating voltage, with respect to the p-doped substrate, ranging from the breakdown voltage to the breakdown voltage minus 20V to 60V, but because of the isolation, each such device experiences a relatively small voltage drop in the range of 20V to 60V. Examples of active devices using a p-well region inside the floating well may be an nMOSFET, an NPN transistor using the p-well region as a base and the n-doped buried layer as a collector, or a 20-60V pMOSFET using the p-well region as a drain extension. As a specific example, shown in FIG. 2 is an nMOSFET comprising n-doped source and drain regions 312 and 314, and gate 316 (underneath gate 316 is an oxide layer). These are merely a few examples, but in general any type of device and process for p-wells may be a candidate for p-wells within a floating well described by the embodiments.

N-well regions inside a floating well, e.g., regions 212 and 216 for the embodiment of FIG. 2, are all at the same voltage potential because they are electrically connected to each other by the n-doped buried layer. Devices fabricated in an n-well within a floating well may have the same operating voltage range as discussed previously with respect to p-wells within the floating well, depending on the device layout and the process. Devices fabricated in an n-well region within a floating well may be a pMOSFET, a lateral PNP device, or other types of devices, where any device that can be fabricated within an n-well may be a candidate for an n-well within a floating well described by the embodiments. As a specific example, shown in FIG. 2 is a pMOSFET comprising p-doped source and drain regions 318 and 320, and gate 322 (underneath gate 322 is an oxide layer).

Various modifications may be made to the described embodiments without departing from the scope of the invention as claimed below.

It is to be understood in these letters patent that the meaning of “A is connected to B”, where for example A or B may be, but are not limited to, a node, a device terminal, or a port, is that A and B are electrically connected to each other by a conductive structure so that for frequencies within the signal bandwidth of interest, the resistance, capacitance, and inductance introduced by the conductive structure may each be neglected. For example, a transmission line (e.g., microstrip), relatively short compared to the signal wavelength of interest, may be designed to introduce a relatively small impedance, so that two devices in electrical contact at each end of the transmission line may be considered to be connected to one another.

It is also to be understood in these letters patent that the meaning of “A is coupled to B” is that either A and B are connected to each other as described above, or that, although A and B may not be connected to each other as described above, there is nevertheless a device or circuit that is connected to both A and B so that a properly defined voltage or current at one of the two elements A or B has some effect on a properly defined voltage or current at the other of the two elements.

What is claimed is:

1. An article of manufacture comprising:
a semiconductor comprising:
a substrate;
an n-doped buried layer adjacent to the substrate;
an n-doped region adjacent to the n-doped buried layer and the substrate, the n-doped region comprising a first n-doped region adjacent to the n-doped buried layer and having a first doping concentration, and a last n-doped region not adjacent to the n-doped buried layer and having a last doping concentration less than the first doping concentration; and
a p-doped region adjacent to the last n-doped region and to the substrate; and
a resistor electrically coupled to the first n-doped region and to the p-doped region.

2. The article of manufacture as set forth in claim 1, wherein the p-doped region is part of the substrate.

3. The article of manufacture as set forth in claim 1, further comprising:
a dielectric layer formed on the n-doped region and the p-doped region, wherein the resistor is formed in the dielectric layer;
a first ohmic contact to electrically couple the resistor to the first n-doped region; and
a second ohmic contact to electrically couple the resistor to the p-doped region.

4. The article of manufacture as set forth in claim 3, wherein
the first ohmic contact comprises a highly doped n-region in the first n-doped region, a first via in the dielectric layer connected to the highly doped n-region, an interconnect connected to the first via, and a second via in the dielectric layer connected to the interconnect and to the resistor; and
the second ohmic contact comprises a highly doped p-region in the p-doped region, a first via in the dielectric layer connected to the highly doped p-region, an interconnect connected to the first via of the second ohmic contact, and a second via in the dielectric layer connected to the interconnect of the second ohmic contact and to the resistor.

5. The article of manufacture as set forth in claim 1, the n-doped region comprising a second n-doped region adjacent to the first n-doped region and the substrate, and having a second doping concentration less than the first doping concentration and greater than the last doping concentration.

6. The article of manufacture as set forth in claim 1, wherein a portion of the resistor surrounds the first n-doped region.

7. The article of manufacture as set forth in claim 6, wherein the resistor surrounds the first n-doped region.

8. The article of manufacture as set forth in claim 6, wherein the resistor has a spiral shape.

9. The article of manufacture as set forth in claim 1, wherein the last n-doped region surrounds the first n-doped region, and the p-doped region surrounds the last n-doped region.

10. The article of manufacture as set forth in claim 9, further comprising an isolated p-doped region adjacent to the first n-doped region and the n-doped buried layer, wherein the first n-doped region surrounds the isolated p-doped region.

11. The article of manufacture as set forth in claim 10, further comprising an active device integrated in the isolated p-doped region.

12. An article of manufacture comprising:
a semiconductor comprising:
a substrate;
a well in contact with the substrate, the well comprising an n-doped buried layer in contact with the substrate, and an n-doped region in contact with the n-doped buried layer;
a graded n-doped region having a graded doping concentration in contact with the substrate and the n-doped region of the well;
a p-doped region in contact with the substrate and the graded n-doped region; and
a resistor electrically coupled to the n-doped region of the well and to the p-doped region.

13. The article of manufacture as set forth in claim 12, wherein the graded n-doped region surrounds the well.

14. The article of manufacture as set forth in claim 13, wherein a portion of the resistor surrounds the well.

15. The article of manufacture as set forth in claim 14, wherein the resistor surrounds the well.

16. The article of manufacture as set forth in claim 12, wherein the graded n-doped region has a stepped doping profile.

17. The article of manufacture as set forth in claim 16, the n-doped region of the well having a doping concentration, wherein
the graded n-doped region comprises
a first n-doped region in contact with the n-doped region of the well, and having a first doping concentration less than the doping concentration of the n-doped region of the well; and
a last n-doped region in contact with the p-doped region, and having a last doping concentration less than the first doping concentration.

18. The article of manufacture as set forth in claim 12, further comprising:
a dielectric layer, wherein the resistor is formed in the dielectric layer;
a first ohmic contact to electrically couple the resistor to the n-doped region of the well; and
a second ohmic contact to electrically couple the resistor to the p-doped region.

19. The article of manufacture as set forth in claim 18, wherein
the first ohmic contact comprises a highly doped n-region in the n-doped region of the well, a first via in the dielectric layer connected to the highly doped n-region, an interconnect connected to the first via, and a second via in the dielectric layer connected to the interconnect and to the resistor; and
the second ohmic contact comprises a highly doped p-region in the p-doped region, a first via in the dielectric layer connected to the highly doped p-region, an interconnect connected to the first via of the second ohmic contact, and a second via in the dielectric layer connected to the interconnect of the second ohmic contact and to the resistor.

20. The article of manufacture as set forth in claim 12, the well further comprising a transistor formed in the n-doped region of the well.

21. The article of manufacture as set forth in claim 12, the well further comprising a p-doped region in contact with the n-doped buried layer, and a transistor formed in the p-doped region of the well.

22. The article of manufacture as set forth in claim 12, wherein the resistor has a spiral shape.

23. The article of manufacture as set forth in claim 12, the well further comprising a p-doped region in contact with the n-doped buried layer and surrounded by the n-doped region of the well, and an active device integrated in the p-doped region of the well.
